(19) United States
(12) Patent Application Publication
(10) Pub. No.: US 2009/0231648 A1
(43) Pub. Date: Sep. 17, 2009

(54) HOLOGRAM SUBSTRATE, METHOD FOR PRODUCING SAME, AND ELECTRONIC DEVICE

(75) Inventors: Shingo Imanishi, Kanagawa (JP); Masayoshi Kanno, Kanagawa (JP); Motohiro Furuki, Tokyo (JP); Eisuke Negishi, Tokyo (JP)

Correspondence Address: K&L Gates LLP, P. O. BOX 1135, CHICAGO, IL, 60690, US

(73) Assignee: Sony Corporation, Tokyo (JP)

(21) Appl. No.: 12/401,932

(22) Filed: Mar. 11, 2009

(30) Foreign Application Priority Data
Mar. 11, 2008 (JP) 2008-061699

(51) Int. Cl. G03H 1/08; G03F 7/004; G03H 1/24

(52) U.S. Cl. 359/2; 430/2

(57) ABSTRACT

A hologram substrate includes a hologram section arranged on a surface of the hologram substrate, the hologram section having an uneven pattern configured to form a holographic image, in which the uneven pattern is a depth-modulated pattern and has smooth boundaries between projections and depressions.

### CROSS REFERENCES TO RELATED APPLICATIONS

The present application claims priority to Japanese Patent Application JP 2008-061699 filed in the Japanese Patent Office on Mar. 11, 2008, the entire contents of which are incorporated herein by reference.

### BACKGROUND

The present application relates to a hologram substrate having an uneven pattern on a surface of the hologram substrate, the uneven pattern being formed by nanoimprinting, a method for producing the hologram substrate, and an electronic device.

Various small, thin auxiliary storage devices having card shapes and the like have been used as storage media for digital cameras, personal computers, and the like. Electronic devices typified by the auxiliary storage devices, such as memory cards, e.g., universal serial bus chips (USB chips), are relatively small, expensive products. The fact that a large number of their counterfeited articles are on the market is problem. To determine the authenticity of manufacturers of these electronic devices, for example, a method of attaching a hologram sticker to a package is employed.

The hologram sticker, however, can be relatively easily counterfeited. Thus, counterfeited articles are easily produced. When a large number of counterfeited articles are produced, consumers misidentify counterfeited articles as certified articles and purchase counterfeited articles. As a result, the reliability of certified articles is reduced, and profits from certified articles are not secured. Furthermore, original manufacturers suffer extensive damage.

As a technique for protecting an article, Japanese Unexamined Patent Application Publication No. 2007-015196 discloses a card with a hologram that has an uneven pattern of a computer-generated hologram and that is formed on a surface of a substrate. In this case, the hologram is directly recorded on the body of the article, authenticity can be easily determined, and the hologram is not easily replicated.

Furthermore, Japanese Unexamined Patent Application Publication No. 2003-256794 discloses an IC card with a hologram formed of a hologram formation layer having an uneven pattern and a hologram effect layer composed of a material having a refractive index different from that of the hologram formation layer, the hologram formation layer being in contact with the hologram effect layer.

### SUMMARY

In the card with the hologram described in Japanese Unexamined Patent Application Publication No. 2007-015196, the uneven pattern of the computer-generated hologram is arranged on the surface of the substrate. Edges of the uneven pattern are relatively angulated. The angular edges cause scattering, disadvantageously reducing the visibility of a hologram image.

In the IC card with the hologram described in Japanese Unexamined Patent Application: Publication No. 2003-256794, the hologram formation layer and the hologram effect layer composed of the material having a refractive index different from that of the hologram formation layer are arranged, thereby improving visibility. In this case, however, the arrangement of the additional layer different from the hologram formation layer increases the number of production steps, thereby disadvantageously resulting in an increase in cost.

It is desirable to suppress the scattering loss due to an uneven pattern constituting a hologram and improve visibility when a hologram image is displayed.

According to an embodiment, there is provided a hologram substrate including a hologram section arranged on a surface of the hologram substrate, the hologram section having an uneven pattern configured to form a holographic image, in which the uneven pattern is a depth-modulated pattern and has smooth boundaries between projections and depressions.

According to another embodiment, there is provided a method for producing a hologram substrate including the steps of forming a master mold by pattern-exposing and developing an inorganic resist containing an incomplete oxide of a transition metal, the master mold having a depth-modulated uneven pattern and being configured to form a metal mold, forming the metal mold from the master mold by plating, pressing the metal mold against a deformable hologram material layer, and curing the hologram material layer.

According to another embodiment, there is provided an electronic device including a housing having the hologram substrate.

In each of a hologram substrate and an electronic device including a housing having the hologram substrate according to an embodiment, a hologram layer having a depth-modulated uneven pattern is formed. In particular, the uneven pattern has smooth boundaries between projections and depressions, thereby suppressing scattering loss at edges of the boundaries between the projections and depressions and thus making it possible to recognize a clearer hologram image.

A method for producing a hologram substrate according to an embodiment includes the steps of forming a master mold by pattern-exposing and developing an inorganic resist containing an incomplete oxide of a transition metal, forming a metal mold from the master mold, pressing the metal mold against a hologram material layer, and curing the hologram material layer. In this way, when pattern exposure and development are performed with the inorganic resist containing the incomplete oxide of the transition metal, the uneven pattern can be formed so as to have relatively smooth boundaries between the projections and depressions, i.e., so as to have round edges of the projections and the depressions. Thus, in the method for producing a hologram substrate according to an embodiment, the scattering loss at the edges of the boundaries between the projections and depressions. The hologram substrate excellent in visibility can be provided without arranging an additional layer other than the hologram material layer.

Additional features and advantages are described herein, and will be apparent from the following Detailed Description and the figures.

### BRIEF DESCRIPTION OF THE FIGURES

FIG. 1 is a schematic perspective view of a hologram substrate according to an embodiment;

FIGS. 2A to 2D are process drawings illustrating a method for producing a hologram substrate according to an embodiment;

FIGS. 3A to 3D are process drawings illustrating a method for producing a hologram substrate according to an embodiment;

FIG. 4A is a schematic cross-sectional view of an uneven pattern according to a comparative embodiment of the present application, and FIG. 4B is a schematic cross-sectional view of an uneven pattern according to an embodiment;

FIG. 5A is a schematic cross-sectional view of an uneven pattern according to a comparative embodiment, and FIG. 5B is a schematic cross-sectional view of an uneven pattern according to an embodiment; and

FIG. 6 is a schematic cross-sectional view of an electronic device including a housing having a hologram substrate according to an embodiment.

### DETAILED DESCRIPTION

The present application is described below in greater detail with reference to the figures according to an embodiment.

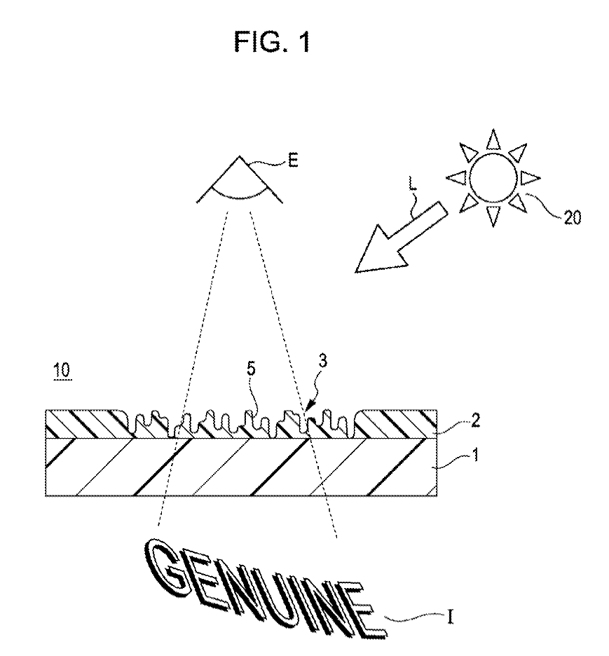

A hologram substrate and a method for producing the same according to a first embodiment will be described below. FIG. 1 is a schematic perspective view of a hologram substrate 10 according to this embodiment. In this embodiment, the hologram substrate 10 includes a sub-substrate 1 composed of a metal such as stainless steel and a hologram material layer 2 composed of plastic such as polyethylene terephthalate or a resin such as printing ink, the hologram material layer 2 being arranged on the sub-substrate 1. A depth-modulated uneven pattern 5 having a three-dimensional structure is formed on the surface of the hologram material layer 2 to form a hologram section 3. The uneven pattern 5 is a depth-modulated pattern and has smooth boundaries between projections and depressions, i.e., round edges of the projections and depressions.

In the case where the uneven pattern 5 of the hologram substrate 10 is irradiated with light L emitted from a light source 20 such as the sun or an incandescent lamp, a virtual image I can be directly recognized in the direction of the uneven pattern 5 when viewed from the eyepoint E of an observer. The uneven pattern 5 that displays such a virtual image can be easily designed as, for example, a depth-modulated pattern represented by a computer-generated hologram.

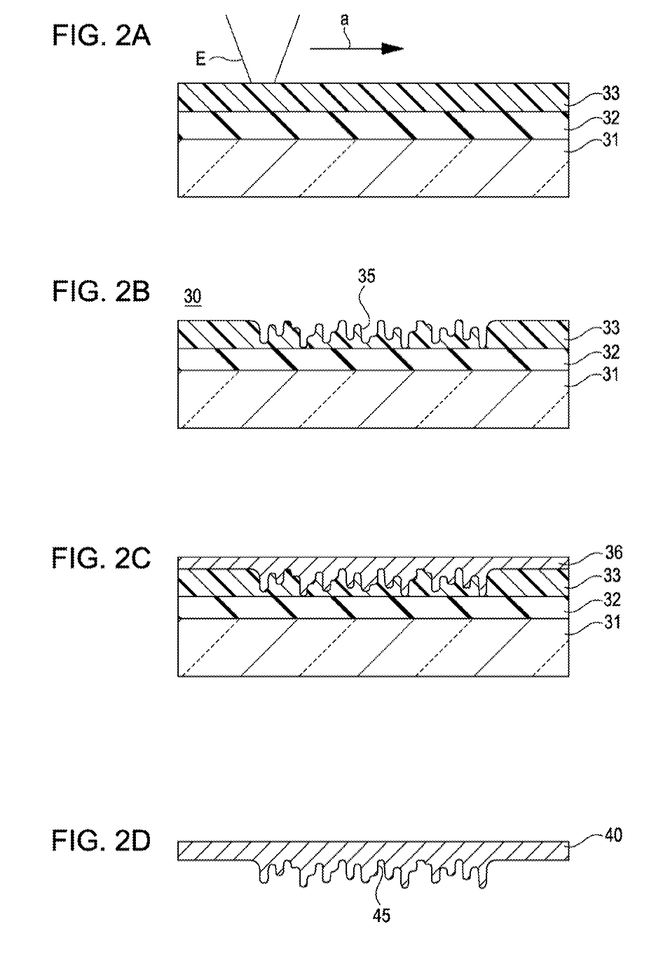

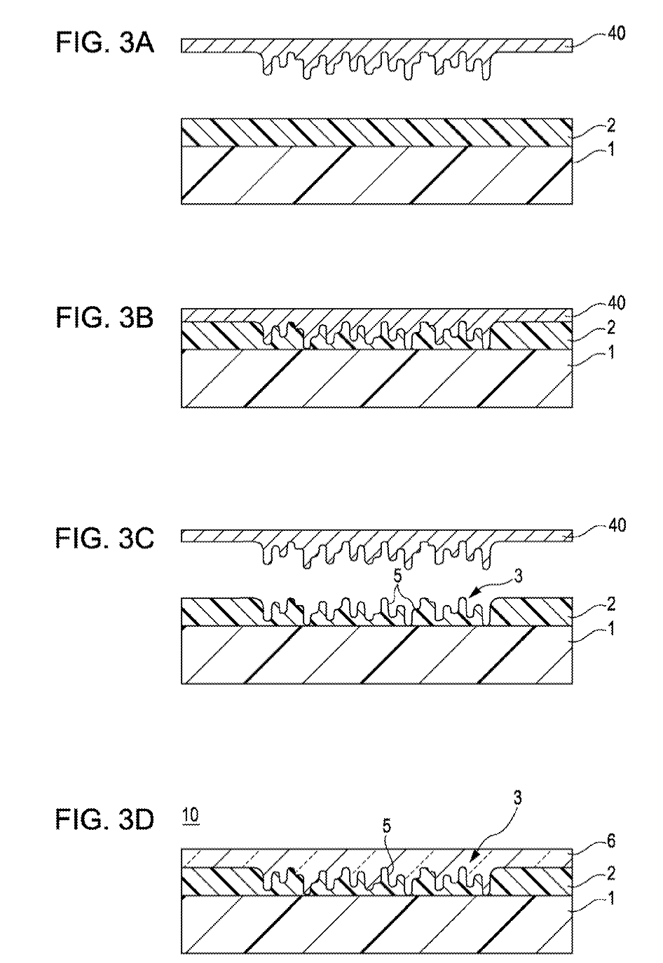

An exemplary method for producing the hologram substrate 10 according to this embodiment will be described below with reference to FIGS. 2A to 3D which are process drawings.

Referring to FIGS. 2A to 2D, the steps of forming a metal mold having an even pattern will be described below. As shown in FIG. 2A, a substrate 31 composed of, for example, Si is prepared. An intermediate layer 32 composed of a material, such as amorphous Si, having a thermal conductivity lower than that of the material constituting the substrate 31 is formed thereon. An inorganic resist 33 composed of, for example, WOₓ or WMoOₓ and containing an incomplete oxide of a transition metal is formed on the intermediate layer 32.

As the inorganic resist 33, a resist material described in our Japanese Patent No. 3879726 can be used. Examples of the transition metal include Ti, V, Cr, Mn, Fe, Nb, Cu, Ni, Co, Mo, Ta, W, Zr, Ru, and Ag. Among these metals, Mo, W, Cr, Fe, or Nb is preferably used. From the viewpoint of obtaining a significant chemical change by irradiation with ultraviolet rays or visible light, Mo or W is particularly preferably used.

Examples of the incomplete oxide of the transition metal that can be used include an incomplete oxide of a single type of transition metal; an incomplete oxide of two types of transition metals; an incomplete oxide of three or more types of transition metals; and an incomplete oxide of a single type of transition metal and an element other than transition metals. In particular, an incomplete oxide of two or more types of metal elements is preferred.

In the incomplete oxide of two types of transition metals and the incomplete oxide of three or more types of transition metals, atoms of one transition metal are believed to be partially substituted by atoms of another transition metal. Whether the oxide is an incomplete oxide or not is determined on the basis of whether the oxygen content is deficient with respect to possible stoichiometric compositions of the multiple types of transition metals.

As the element other than transition metals, at least one element selected from Al, C, B, Si, and Ge can be used. A combination of two or more types of transition metals or the addition of the element other than transition metals results in a reduction in the grain size of the resulting incomplete oxide of the transition metal(s). This clarifies the boundary between exposed and unexposed areas, thereby significantly improving the resolution and the sensitivity to exposure.

In the case of using the inorganic resist 33 composed of the materials, exposure can be performed without using a special exposure light source such as a device that emits electron beams or ion beams because the inorganic resist 33 absorbs ultraviolet rays or visible light. The incomplete oxide of the transition metal(s) has a low molecular weight. Thus, the boundary between exposed and unexposed areas is clear compared with an organic resist composed of a polymer. Accordingly, the use of the inorganic resist 33 provides a high-precision nanoscale resist pattern having a pitch of less than 1 μm and a width of less than 1 μm. Furthermore, in the case where irradiation power exceeds a threshold level, the width and depth can be obtained in proportion to irradiation intensity. The adjustment of the irradiation power makes it possible to easily form a latent image of an uneven pattern having different depths by exposure.

Examples of a material constituting the substrate that can be used include glass, plastic such as polycarbonate, alumina-titanium carbide, and nickel in addition to silicon described above.

The inorganic resist 33 is preferably formed by sputtering on the substrate 31 composed of the material. For example, sputtering is performed with a target containing a transition metal in an atmosphere of Ar+O₂ while the flow rate of O₂ gas is regulated. The flow rate of O₂ gas is set at, for example, 5% to 20% with respect to the total flow of gases introduced into a chamber. The gas pressure is set at 1 to 10 Pa, which is commonly used in sputtering.

Any thickness of the inorganic resist 33 can be used. The inorganic resist 33 may have a thickness such that depressions having the maximum depth in a target uneven pattern are successfully formed.

In the case where the substrate 31 is composed of a material, such as single crystal silicon, having a relatively high thermal conductivity, a material layer having a thermal conductivity lower than that of the substrate 31 is preferably formed as the intermediate layer 32 as described above. The arrangement of the intermediate layer 32 permits the adjustment of thermal storage in the inorganic resist 33 during exposure to light, thereby appropriately improving the sensitivity to exposure. Examples of a material constituting the intermediate layer 32 that can be used include silicon dioxide (SiO₂), silicon nitride (SiN), and alumina (Al₂O₃) in addition to amorphous silicon described above. These materials can be deposited by, for example, sputtering or evaporation. The thickness of the intermediate layer 32 may be appropriately determined in view of the thermal conductivity of a material constituting the intermediate layer 32 and the range of adjustment of the sensitivity to exposure.

The inorganic resist 33 is subjected to exposure to light in order to form an uneven pattern corresponding to a target holographic image. An exposure process is as follows: The substrate 31 is placed on a support. As shown in FIG. 2A, exposure light E scans in the direction indicated by the arrow a. The use of a galvano-mirror or polygon mirror as a scanning element permits high-speed scanning over the surface. Alternatively, the substrate 31 may be placed on a movable stage such as an x-y stage or a turntable and irradiated with the exposure light while the stage is being horizontally displaced or rotated. Furthermore, relative scanning may be performed by combining scanning and the displacement and rotation of the stage. As described above, the modulation of the power during exposure permits the formation of a latent image of an uneven pattern having different depths in the inorganic resist 33.

Development is performed to form an uneven pattern 35 on a surface of the inorganic resist 33 as shown in FIG. 2B. Thereby, a master mold 30 for a metal mold is provided. The development can be performed by a wet process using acid or alkaline solution or a dry process such as plasma etching or reactive ion etching. The uneven pattern 35 is a depth-modulated pattern formed by the modulation of the power of the exposure light and, in particular, has round edges of the boundaries between the projections and depressions.

After a release layer and a plating underlying layer (not shown) are formed, a plating layer 36 is formed by Ni plating as shown in FIG. 2C. Referring to FIG. 2D, the plating layer 36 is separated to afford a metal mold 40 having an uneven pattern 45 which is the reversal pattern of the uneven pattern 35.

The steps of forming a hologram substrate using the resulting metal mold 40 will be described below. Referring to FIG. 3A, the sub-substrate 1 composed of, for example, stainless steel or a resin, which can be used as a material for a housing of an electronic device such as a USB chip, is prepared. The hologram material layer 2 composed of a plastic resin or printing ink is formed on a predetermined area of a surface of the sub-substrate 1 by printing or the like. The sub-substrate 1 and the hologram material layer 2 may be integrally formed with a single material.

The hologram material layer 2 is brought into a deformable state. The hologram material layer 2 composed of a thermosetting resin can be used without processing. For the hologram material layer 2 composed of a thermoplastic resin such as printing ink, the hologram material layer 2 is brought into a semi-cured state by heating the sub-substrate 1. In the case where the sub-substrate 1 and the hologram material layer 2 are both composed of a plastic resin, at least a surface of the hologram material layer 2 composed of the plastic resin is brought into a semi-cured state. Heating conditions may be appropriately determined in response to the materials constituting the hologram material layer 2 and the sub-substrate 1. The metal mold 40 is arranged above the hologram material layer 2 while this state is maintained. As shown in FIG. 3B, the metal mold 40 is pressed toward the sub-substrate 1 by nanoimprint lithography to transfer the uneven pattern into the hologram material layer 2 on the sub-substrate 1.

As shown in FIG. 3C, the metal mold 40 is separated from the hologram material layer 2, resulting in the uneven pattern 5, which is the reversal pattern of the uneven pattern 45 of the metal mold 40, on the surface of the hologram material layer 2 on the sub-substrate 1. Then the hologram material layer 2 is cured. That is, in the case of the hologram material layer 2 composed of a thermoplastic resin, the hologram material layer 2 is cooled. In the case of the hologram material layer 2 composed of a thermosetting resin, the hologram material layer 2 is heated.

As shown in FIG. 3D, a protective layer 6 composed of a material such as an optically transparent resin is formed on the uneven pattern 5 by application or the like. A reflective layer may be formed between the uneven pattern 5 and the protective layer 6, as needed. Examples of a material constituting the reflective layer include metals, such as Au, Ag, and Al, and alloys. The reflective layer can be formed by sputtering or the like. The steps described above are performed to provide the hologram substrate 10 including the hologram section 3 having the uneven pattern 5 on the surface thereof.

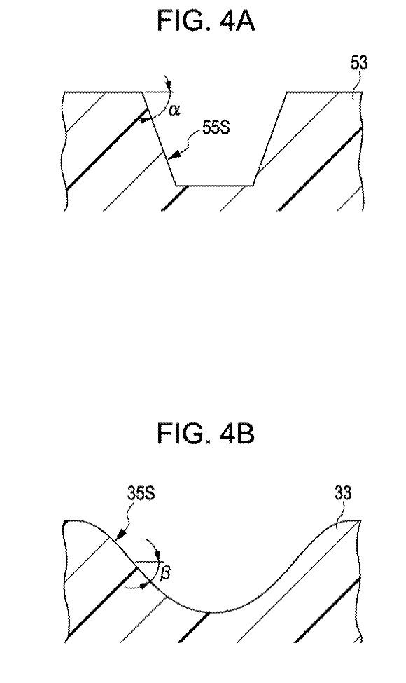

As described above, in the resulting hologram substrate 10, the uneven pattern 5 constituting the hologram section 3 formed on the surface thereof has smooth boundaries of the projections and the depressions and has round edges of the projections and depressions. This will be explained below with reference to FIGS. 4A and 4B. In the case of using a common organic resist, as shown in FIG. 4A, an uneven pattern has a relatively angulated edge of the boundary between a projection and a depression of an organic resist 53. The angle α of a slope 55S, which is a side face of the depression and the projection, to a horizontal plane is about 70° to about 80°. In contrast, as shown in FIG. 4B, in the case of using the inorganic resist 33, the angle β of a slope 35S, which is a side face of a depression and a projection, to a horizontal plane is relatively small and about 50°. The edge is a gentle slope and has a roundish shape.

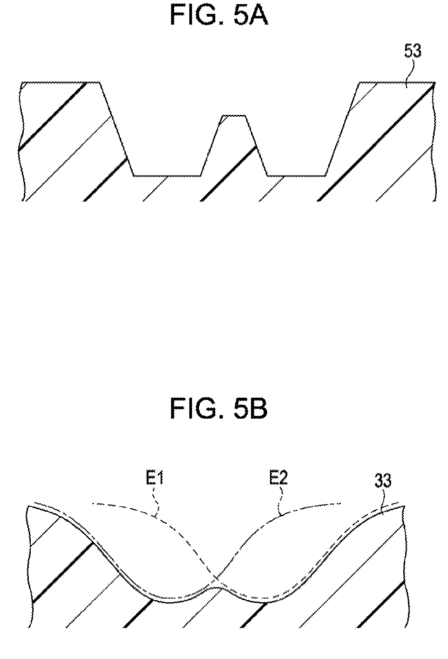

Also in the case of a pattern in which adjacent exposed areas are partially overlapped, different shapes are obtained. As shown in FIG. 5A, in the case of using the organic resist 53, boundaries between projections and depressions has relatively steep side faces. A projection located between two depressions has relatively angulated edges. In contrast, as shown in FIG. 5B, in the case of using the inorganic resist 33, a gently sloping shape is obtained as a whole. A projection located between two depressions also has roundish edges.

Thus, the formation of the uneven pattern 5 with the metal mold formed using the inorganic resist containing the incomplete oxide of the transition metal results in the suppression of scattering loss when the uneven pattern 5 is irradiated with light, thereby improving the visibility of a hologram image.

In the case of using the organic resist, it is difficult to form a depth-modulated uneven pattern because the depressions have relatively rough surfaces after development or pattern etching. Thus, an uneven pattern having a uniform depth corresponding to the thickness of the organic resist is usually formed. In contrast, in the case of using the inorganic resist 33, the depressions have relatively smooth surfaces. Thus, it is possible to form the uneven pattern having different depths with satisfactory surface quality.

In this embodiment, as shown in FIG. 3D, the formation of the protective layer 6 in which the uneven pattern 5 is embedded advantageously results in the protection of the fine shape of the uneven pattern 5 and difficulty in replication. The formation of a reflective layer (not shown) on the uneven pattern 5 further improves the visibility. In the case of using the sub-substrate 1 composed of a lustrous metal, it is sufficiently possible to satisfactorily identify a hologram image without the reflective layer.

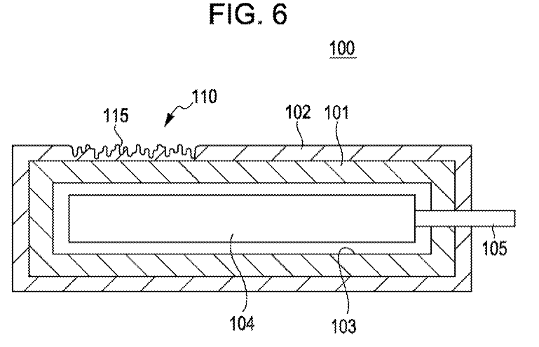

The hologram substrate described above can be applied to housings of various electronic devices typified by auxiliary storage devices such as memory cards. FIG. 6 is a schematic cross-sectional view of an exemplary electronic device including a housing having a hologram substrate according to the foregoing embodiment.

FIG. 6 shows an electronic device 100 that can be applied to, for example, USB memory devices and memory cards. As shown in FIG. 6, the electronic device 100 is in the form of a stick or card and includes a substrate 101 having a cavity 103 therein, a hologram material layer 102 arranged on a surface of the substrate 101, an electronic component 104 having a memory element and a control circuit therein, and a terminal extending from the electronic component 104 toward the outside. The cavity 103 may be filled with a protective material or the like. A structure in which at least part of the electronic component 104 is in contact with an inner surface of the substrate 101 may be used. In this example shown in the figure, the structure having the substrate 101 composed of a metal or the like and the hologram material layer 102 formed by printing is illustrated. Alternatively, the substrate and the hologram material layer which are composed of a plastic resin or the like may be integrally formed. In this case, a hologram section 110 including an uneven pattern 115 is formed on part of a surface of the hologram material layer 102. The uneven pattern 115 in the hologram section 110 is formed by imprinting with a metal mold which is formed using the inorganic resist containing the incomplete oxide of the transition metal described above. The uneven pattern 115 is a depth-modulated pattern and has smooth boundaries between projections and depressions.

The electronic device 100 including the housing having the uneven pattern 115 on the surface thereof permits the recognition of a virtual image of the hologram by irradiation with common light from the sun or an incandescent lamp, easily determining authenticity. In this case, scattering loss at edges of the uneven pattern 115 is suppressed to improve visibility compared with electronic devices having hologram patterns according to the related art.

In FIG. 6, a reflective film, a protective film, and the like are not formed on the uneven pattern 115. Of course, these optical functional films may be formed on the uneven pattern 115. The arrangement of the reflective film further improves the visibility of an image. The arrangement of the protective film suppresses or prevents damage to the uneven pattern 115 caused by the contact or pressing of other objects.

As has been described, in the case of a product including the hologram substrate according to an embodiment, the replication is difficult compared with a method for attaching a sticker in the related art; hence, the reliability of determination of authenticity is improved. Furthermore, the authenticity can be checked without using a special light source. Thus, the public can easily determine the authenticity.

In the method for producing the hologram substrate according to an embodiment, the formation of the uneven pattern with the inorganic resist containing the incomplete oxide of the transition metal results in the suppression of a reduction in visibility due to scattering loss at the edges of the uneven pattern, thereby making it possible to determine authenticity with the hologram excellent in visibility. The fine nanoscale pattern constituting the hologram is not, easily replicated, thus achieving high reliability of determination of the authenticity. Even in the unlikely event that the pattern is replicated, the fine uneven pattern is distorted; hence, the hologram is not precisely replicated.

Furthermore, the formation of the reflective film on the uneven pattern further improves the visibility of the hologram. In addition, the formation of the optically transparent protective film in which the uneven pattern is embedded results in the protection of the fine pattern and difficulty in replication.

The present application is not limited to those structures described in the foregoing embodiments. Various modifications and changes can be made without departing from the scope of the application. For example, an additional layer or another structure may be arranged in a region where the hologram section on the surface of the hologram substrate is not arranged.

A device including a housing having the hologram substrate is not limited to the foregoing electronic devices. Various products, such as auxiliary storage devices having various shapes and digital cameras and computers including such auxiliary storage devices, which call for determination of authenticity, may include housings having the hologram substrates.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A hologram substrate comprising:
a hologram section arranged on a surface of the hologram substrate, the hologram section having an uneven pattern configured to form a holographic image,
wherein the uneven pattern is a depth-modulated pattern and has smooth boundaries between projections and depressions.

2. The hologram substrate according to claim 1,
wherein at least a surface of the hologram substrate is composed of a resin, and the uneven pattern is composed of the resin.

3. The hologram substrate according to claim 1,
wherein when the uneven pattern arranged on the surface of the hologram substrate is irradiated with illumination light, a virtual image is recognized.

4. The hologram substrate according to claim 3,
wherein sunlight or light from an incandescent lamp can be used as the illumination light.

5. A method for producing a hologram substrate, comprising:
forming a master mold by pattern-exposing and developing an inorganic resist containing an incomplete oxide of a transition metal, the master mold having a depth-modulated uneven pattern and being configured to form a metal mold;
forming the metal mold from the master mold by plating;
pressing the metal mold against a deformable hologram material layer; and
curing the hologram material layer.

6. The method according to claim 5,
wherein the hologram material layer is composed of a thermoplastic resin or a thermosetting resin.

7. The method according to claim 5, further comprising:
forming at least one of a reflective layer and a protective layer on the hologram material layer.

8. The method according to claim 5,
wherein an uneven pattern transferred from the metal mold is a hologram pattern, and
wherein when the uneven pattern is irradiated with illumination light, a virtual image is recognized.

9. An electronic device comprising:
a housing including a hologram section arranged on a surface of the housing, the hologram section having an uneven pattern configured to form a holographic image, and
an electronic component incorporated in the housing,
wherein the uneven pattern is a depth-modulated pattern and has smooth boundaries between projections and depressions.
